(19) United States
(12) Patent Application Publication
(10) Pub. No.: US 2006/0059411 A1
(43) Pub. Date: Mar. 16, 2006

(54) Method and system for increasing channel coding gain

(75) Inventor: Behram Mario Dacosta, San Diego, CA (US)

Correspondence Address: O'BANION & RITCHEY LLP/ SONY ELECTRONICS, INC., 400 CAPITOL MALL, SUITE 1550, SACRAMENTO, CA, 95814, US

(73) Assignee: SONY CORPORATION AND SONY ELECTRONICS, INC.

(21) Appl. No.: 10/944,176

(22) Filed: Sep. 16, 2004

(51) Int. Cl. H03M 13/03

(52) U.S. Cl. 714/794

(57) ABSTRACT

A system and method for correcting packet error within streaming audio-video packet communication systems (i.e. MPEG-2) instead of disposing of erroneous packets. Information about the packet stream is utilized to estimate corrections which are applied in attempts to correct the packet. In one embodiment corrected packets are sent back through the decoder in an iterative process until the packets are sufficiently corrected or until a limit is reached on the allowable correction time or number of iterations. The estimations can be implemented as hardware, software, or a combination of hardware and software coupled to, or integrated within a streaming packet decoder. The estimations can also be performed in response to packet stream information received from other portions of the decoder or from subsequent driver stages to which the correct packets, or corrected packets, are sent.

### CROSS-REFERENCE TO RELATED APPLICATIONS

Not Applicable

### STATEMENT REGARDING FEDERALLY SPONSORED RESEARCH OR DEVELOPMENT

Not Applicable

### INCORPORATION-BY-REFERENCE OF MATERIAL SUBMITTED ON A COMPACT DISC

Not Applicable

### NOTICE OF MATERIAL SUBJECT TO COPYRIGHT PROTECTION

A portion of the material in this patent document is subject to copyright protection under the copyright laws of the United States and of other countries. The owner of the copyright rights has no objection to the facsimile reproduction by anyone of the patent document or the patent disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. § 1.14.

### BACKGROUND OF THE INVENTION

1. Field of the Invention

The invention pertains generally to digital streaming media packet communications, and more particularly to increasing channel coding gain in response to estimating packet corrections.

2. Description of Related Art

The communication of digital streaming media, such as video, audio, and the like are being pushed toward higher data rates and into noisier channels. To this end, it will be appreciated that even high-definition video is being directed over wireless and power-line communication systems.

In order to provide sufficient quality of service over these noisy channels a number of error correction schemes have been applied. One common form of error correction is referred to as “forward error correction” (FEC), in which additional signals (redundant information) are applied at the transmitting end which are utilized for detecting errors contained in packets at the receiving end. The information encoding may use convolution encoding at the transmitter, wherein the receiver may then rely on decoding using a Viterbi algorithm, or similar, to recover the incorrectly transmitted bits and thus increase signal quality by reducing bit error rate (BER).

After decoding the information packet at the receiver, an error detection algorithm (i.e. CRC checking) within the decoder, or coupled to the decoder, flags the packet as either an error-free packet (correct packet), or an erroneous packet. Erroneous packets are typically dropped and are not passed to later modules. The loss of these packets decreases the available channel coding gain resulting in a lower quality of service or the necessity to increase bandwidth utilization to carry the stream.

FIG. 1 depicts a conventional packet receiving scheme in which error detection (ED) within the decoder is shown eliminating erroneous packets into a bit bucket figurative drawn as a garbage can. It can be seen that in response to any detected error, regardless of severity, all information from the errored packet is lost to the system. In the figure according to this example, the decoder is considered to comprise a portion of a Media Access Control (MAC) device driver at the receiver.

It should be noted that Media Access Control (MAC) is the lower sublayer of the OSI data link layer, the interface between the Logical Link Control of a node and the physical layer of the network. The MAC differs for various physical media, such as wireless media, power-line media, wired Ethernet, and so forth. The MAC sublayer is primarily concerned with breaking data up into data frames, transmitting the frames sequentially, processing the acknowledgment frames sent back by the receiver, handling address recognition, and controlling access to the medium.

The conventional packet decoding described above suffers from a number of drawbacks. Primarily the problems stem from packets being flagged and discarded as erroneous packets regardless of the number of bit errors, or severity of the bit errors. So although the packet data may be substantially correct, and there may exist insufficient bandwidth or latency to resend the packet, the packet is tossed and not communicated to subsequent layers in the device driver.

It will be appreciated, therefore, that a need exists for increasing channel coding gain by utilizing the available information about the packets in the stream so that the information in these packets is not lost. The present invention fulfills that need, as well as others, and overcomes drawbacks inherent with previous solutions.

### BRIEF SUMMARY OF THE INVENTION

A system and method are described for increasing channel coding gain within noisy channels by utilizing known information about the packet stream, such as field characteristics, for estimating packet error corrections. Erroneous packets are thus not just dropped by the system, but are further processed according to knowledge about the stream. In this way many of the errors can be remedied which improves coding gain.

The correction estimation processing is preferably based on known field relationships, from simple relationship to complex relationships, such as the fixed length or other predictable content, sequence number incrementing, calculation of duration field, field change expectations based on heuristics, and so forth. In other words the knowledge of field characteristics preferably comprises a knowledge of how the field changes with respect to time, packet sequence, or in relation to other fields in the past, present or less preferably a short time into the future (i.e. utilizing in this case any available “look-ahead” capabilities).

By way of example estimation of corrections is performed iteratively with the detection of errors, wherein multiple correction passes may be performed to provide sufficient correction. Preferably, the correction time and/or number of correction passes is constrained so that packets are not unduly delayed. If a packet cannot be sufficiently corrected then it may still be passed through to the subsequent layer as portions of the data may still provide utility to that stage.

The present invention disclosed herein, and its various embodiments, can be described in a number of alternative ways. An embodiment of the invention may be described as an apparatus for decoding streaming packets (i.e. streaming media packets containing video and/or audio, such as MPEG-2), comprising: (a) a packet decoder; (b) a packet error detector configured for detecting erroneous packets being decoded; and (c) means for estimating corrections on erroneous packets in response to knowledge of field characteristics.

In one embodiment of the invention the means for estimating corrections can be configured to send the corrected packet back through the packet decoder, providing iterative checking and/or correction. Additionally, a means can be incorporated for limiting the time period or number of iterations over which estimation of corrections is performed on the erroneous packets.

An embodiment of the invention may also be described as an apparatus for decoding streaming packets, comprising: (a) a packet decoder; (b) a packet error detector configured for detecting erroneous packets being decoded; and (c) a packet correction estimator configured for receiving erroneous packets and estimating a packet correction in response to knowledge of field characteristics.

The packet error detector preferably executes Maximum Likelihood estimation techniques, based on the method for FEC channel coding. The more preferable types of FEC channel codes that can be utilized with the proposed technique include convolutional encoding, Viterbi decoding, Reed-Solomon coding, Low Density Parity Check Coding, and Turbo Encoding.

The knowledge of field characteristics used within the estimator is preferably based on fields having fixed packet locations, for example: wireless header information, real-time transport protocol (RTP) header information, internet protocol (IP) header information, MPEG2 header information, duration field, sequence number field, payload type field, length field, time to live (TTL) field, protocol field, source IP address field, destination IP address field, as well as combinations thereof and alternatives which would be recognized by one of ordinary skill in the art.

An embodiment of the invention may also be described as an improvement to a video streaming decoder configured for detecting erroneous packets. The improvement comprises: (a) estimating corrections for an erroneous packet in response to knowledge of field characteristics; and (b) applying correction to the erroneous packet to create a corrected packet. The corrected packet, if not fully corrected, can be sent back into the decoder a sufficient number of times to provide a sufficient level of correction.

Embodiments of the present invention can also be described in terms of a method of decoding streaming data, comprising: (a) detecting at least one error in a packet being decoded; (b) estimating a packet correction for the erroneous packet in response to knowledge of field characteristics; and (c) applying correction to the packet; and (d) sending a packet along to the next driver level for further processing. The estimating and applying of packet correction is preferably performed during the decoding process within the receiver. The estimating and applying of corrections to the packet is preferably performed iteratively until sufficient correction has been applied. The knowledge of field characteristics preferably comprises a knowledge of how the field changes with respect to time or packet sequence, such as within the headers or relating the other fields within each packet.

Another embodiment of the invention can be also be described as a method of decoding streaming data, comprising: (a) decoding a packet; (b) detecting that the packet is erroneous, or sending a correct packet along to next driver level for further processing; (c) estimating a packet correction for the erroneous packet in response to knowledge of field characteristics; (d) applying correction to the packet; and (e) sending corrected packet back to decoder for error checking.

It should be appreciated that the present invention provides a number of beneficial aspects including but not limited to the following.

An aspect of the invention is to provide increased channel coding gain for streaming packet receivers.

Another aspect of the invention is to provide for increased utilization of the available packet information from erroneous packets based on field knowledge.

Another aspect of the invention is to provide a readily implemented mechanism for increasing channel gain.

Another aspect of the invention is to provide a mechanism for increasing channel gain that can be implemented in hardware and/or software.

Another aspect of the invention is to provide increased channel gain for noisy communication medium, such as utilizing forward error correction (FEC) or similar techniques for error detection.

Another aspect of the invention is to provide increased channel gain for wireless links, such as according to IP-based IEEE 802.11 standards.

Another aspect of the invention is to provide a mechanism for correcting errors detected in the decoder within a MAC/device driver.

Another aspect of the invention is to provide a correction estimation process which incorporates a Maximum Likelihood Estimation technique within the receiver.

Another aspect of the invention is to provide a method of increasing coding gain with iterative correction estimation wherein iterations proceed until a sufficient level of “correction” has been obtained.

A still further aspect of the invention is to provide a receiver coding gain technique within limited time or iterative constraints on the iterative correction.

Further aspects of the invention will be brought out in the following portions of the specification, wherein the detailed description is for the purpose of fully disclosing preferred embodiments of the invention without placing limitations thereon.

### BRIEF DESCRIPTION OF THE SEVERAL VIEWS OF THE DRAWING(S)

The invention will be more fully understood by reference to the following drawings which are for illustrative purposes only:

FIG. 1 is a block diagram of conventional error processing within the packet stream decoder of a receiver.

FIG. 2 is a block diagram of a decoder which provides enhanced coding gain according to an embodiment of the present invention.

FIG. 3 is a flowchart of performing a method of enhanced coding gain according to an embodiment of the present invention.

### DETAILED DESCRIPTION OF THE INVENTION

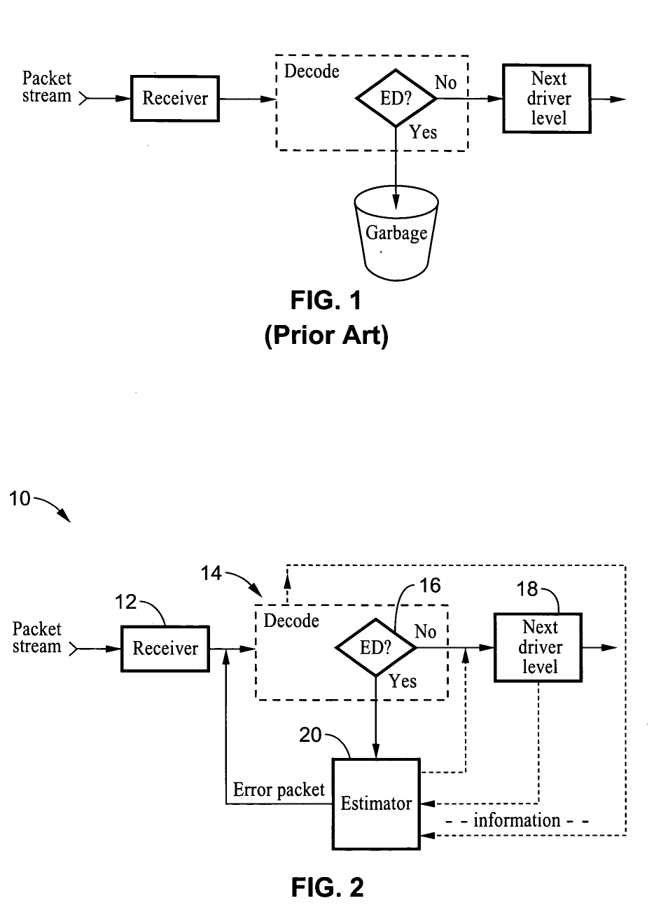

Referring more specifically to the drawings, for illustrative purposes the present invention is embodied in the apparatus generally shown in FIG. 1 through FIG. 3. It will be appreciated that the apparatus may vary as to configuration and as to details of the parts, and that the method may vary as to the specific steps and sequence, without departing from the basic concepts as disclosed herein.

The solution described by the present invention is configured so that erroneous packets are not automatically discarded by the decoder within a receiver. Instead the erroneous packets can be directed to the upper MAC/device driver, the initial stages of which can be implemented in hardware, software, or a combination of hardware and software. In this way the system gives additional consideration to information that was otherwise irretrievable lost. As a consequence of retaining this information and processing it using the estimator described herein, the resultant channel coding gain for the system can be increased.

FIG. 2 illustrates an embodiment 10 of a system in which error detection (ED) within the decoder is shown utilizing erroneous packets according to the present invention. Although suitable to a number of different applications, an embodiment of the technique is described for use with internet protocol (IP) based Motion Picture Experts Group (MPEG) 2 video stream coding over a wireless data link such as an IEEE 802.11a wireless link, the type of application to which it is particularly well suited. In the figure packets are shown in a packet stream being received by a receiver 12 and passed to a decoder 14 which includes error detection mechanism 16. Erroneous packets are corrected by a means for estimating corrections, such as in response to being passed to a correction estimator 20 that estimates and applies correction to the packets and in a preferred embodiment routes the corrected packets back to the decoder, wherein they are checked for sufficient correction. Correct packets as well as corrected packets are communicated to the next driver level 18 for processing, or alternatively, any stage which utilizes the streaming packets.

It can be seen in the figure that packet correction estimates can be generated by estimator 20 in response to information received from portions of the decoder or other system elements, such as the subsequent driver level, to aid in driving the correction. In addition, an optional path is shown for corrected packets to be passed from estimator 20 to the next level, such as in response to the estimator being integrated with the decoder. The estimator may perform the estimations based on the entire packet, or separately in response to separate field portions of the packets.

Packet correction within the present invention is preferably performed in response to rules-based reasoning, likelihood probabilities, heuristics and so forth which estimate correction to the packets. Knowledge of packet contents effectively provides a context within which the receiver is able to decode packets and to correct a substantial number of packet errors. The estimations are preferably based on analyzing field values against known field patterns or relationships between sequential field data. The protocol and codec specific information available in each packet, and across packets, can be utilized to improve the Maximum Likelihood Estimation that occurs at the receiver. By way of example, Maximum Likelihood Estimation schemes include Trellis encoding and decoding utilizing Viterbi algorithms, as well as Low Density Parity Check Coding, and Turbo Encoding.

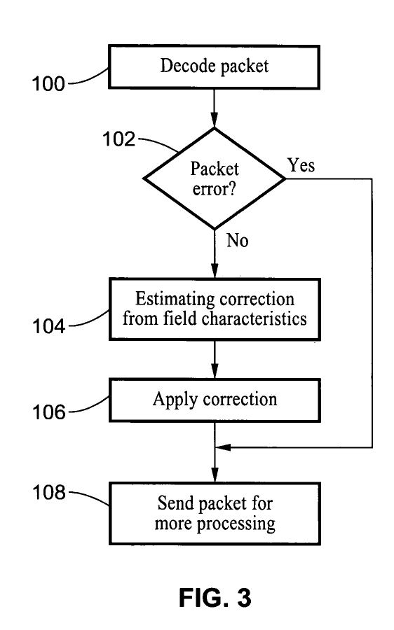

FIG. 3 illustrates an embodiment of the method for increasing channel coding gain in the decoder of a receiver utilizing the field knowledge-based correction estimation described herein. A packet is being decoded as represented by block 100 and a packet error determination is made at block 102. Corrections are then estimated from packet stream knowledge, in particular the field characteristics, as per block 104. The corrections are applied as depicted in block 106, after which the corrected packet is sent for use or further processing as per block 108.

The technique can be utilized with, or without, the addition of error concealment techniques applied to packets that cannot be fully corrected, such as incorporated within block 108. The use of error concealment and similar techniques can further increase the channel coding gain of the system. Error concealment techniques are known in the art and their specific implementation, therefore, need not be discussed herein.

The knowledge for estimating correction can be derived from a number of sources. For example, considering information from within an IEEE 802.11a header, every packet includes specific fields in the PHY and MAC headers. The physical location of these fields is fixed for all packets. When streaming from a video server to a video client, and in many other applications, the contents of a number of the packet fields have a known relationship to the same fields in previously received packets (and optionally to future packets in the case of receivers incorporating look-ahead buffer mechanisms). For example, the source and destination address of the packet can be reasonably expected to be the same as that of previously received packets. It will also be noted that the packet sequence number is related to previous packet sequence numbers and will often follow according to a simple incremental advance when all packets are being received. The duration field of the transmitted header is a field that can be readily calculated, and is typically the same as for prior packets if the packet sizes remain constant.

Considering an example for real-time transport protocol (RTP) and internet protocol (IP) embedded within the IEEE 802.11a packet, the RTP and IP header information has fixed locations and predictable contents. Included in these fields are a sequence number, payload type, length, time to live (TTL), protocol, as well as source and destination IP addresses.

By way of further example, there is header information available within the MPEG-2 headers. Each of the MPEG-2 transport stream packets has a periodic 4 byte header every 188 bytes. The MPEG-2 program stream packets have a predictable header location and contents. Additional fields may be estimated by evaluating data across successive packets.

The content-specific information, such as exemplified above, is utilized within the present invention to increase the accuracy of information decoding within the receiver, based on estimating corrections. In a simple implementation, when the decoding module on the receiver detects an error in the decoded packet, it passes the packet to a knowledge-based estimator which utilizes rule-based reasoning and likelihood probabilities to suggest likely values for erroneous bits wherever possible within the erroneous packet. The modified, and ostensibly corrected packet, is preferably passed back to the decoding module for a second pass at Maximum Likelihood Estimation, such as using Viterbi, Low Density Parity Checks, or other standard techniques. The resulting packet, if it still contains errors, can again be passed to the knowledge-based estimator module, wherein an iterative process can proceed until either (1) no further errors are detected, or (2) a iteration threshold is reached, such as based on a predetermined time, number of iterations, or a combination thereof. If the iteration threshold is reached, then the most recent “partially corrected” packet, or the packet having the least significant errors found within the group of partially corrected solutions (i.e. all solutions or within a subset of all solutions) are passed to the higher levels of the MAC/driver as the received packet. It will be appreciated that the significance of the detected errors may be estimated from the error detection code, if implemented, or from other techniques, such as simple Hamming distance determinations between the decoded packet and the knowledge-based estimated packet.

In the example embodiment of video streaming, the later modules of the MAC/driver can then apply video error concealment algorithms to packets that have not been corrected for errors. It should also be readily apparent that the system can be alternatively implemented in a number of ways without departing from the teachings of the present invention. By way of example, instead of the two-level iterative method outlined above, the decoding module can include knowledge of the stream contents directly into its estimation algorithms for each Maximum Likelihood Estimate.

The present invention describes a method and system for providing increased channel coding gain within a packet-based receiver. A number of novel aspects of the invention are disclosed which may be practiced separately or in various combinations without departing from the teachings of the present invention. It will be appreciated that implementation of certain aspects of the invention would be known to one of ordinary skill in the art based on the teachings provided herein, and these additional implementation details have been generally omitted herein.

Although the description above contains many details, these should not be construed as limiting the scope of the invention but as merely providing illustrations of some of the presently preferred embodiments of this invention. Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.”

What is claimed is:

1. An apparatus for decoding streaming packets, comprising:
a packet decoder;
a packet error detector configured for detecting erroneous packets being decoded; and
means for estimating corrections on erroneous packets in response to knowledge of field characteristics.

2. An apparatus as recited in claim 1, wherein said means for estimating corrections is configured to send the packet upon which corrections have been estimated back through said packet decoder.

3. An apparatus as recited in claim 2, further comprising a means for limiting the time period or number of iterations over which estimation of corrections is performed on said erroneous packets.

4. An apparatus as recited in claim 1, wherein said streaming packets comprise streaming media packets containing video, audio, or a combination of video and audio.

5. An apparatus for decoding streaming packets, comprising:
a packet decoder;
a packet error detector configured for detecting erroneous packets being decoded; and
a packet correction estimator configured for receiving erroneous packets and estimating a packet correction in response to knowledge of field characteristics.

6. An apparatus as recited in claim 5, wherein said packet error detector executes Maximum Likelihood estimation.

7. An apparatus as recited in claim 6, wherein said Maximum Likelihood estimation is performed according to the technique selected from the group of estimation techniques consisting essentially of: convolutional encoding, Viterbi decoding, Reed-Solomon coding, Low Density Parity Check Coding, and Turbo Encoding.

8. An apparatus as recited in claim 5, wherein said streaming packets comprise streaming media packets containing video, audio, or a combination of video and audio.

9. An apparatus as recited in claim 8, wherein said streaming packets comprise MPEG-2 stream packets.

10. An apparatus as recited in claim 5, wherein said packet correction estimator is configured to send the corrected packet back through the packet decoder.

11. An apparatus as recited in claim 10, wherein the correcting of packets by the correction estimator and the sending of corrected packets back through the packet decoder is performed in response to a time period limitation, or number of iterations limitation, or a combination time and iteration limitation.

12. An apparatus as recited in claim 5, wherein said knowledge of field characteristics is based on fields selected from the group of fields having fixed packet locations consisting essentially of: wireless header information, real-time transport protocol (RTP) header information, internet protocol (IP) header information, MPEG2 header information, duration field, sequence number field, payload type field, length field, time to live (TTL) field, protocol field, source IP address field and destination IP address field.

13. An apparatus as recited in claim 5, wherein said packet correction estimator is configured for receiving additional field knowledge from said packet decoder or a following driver level to which correct, or corrected, packets are sent.

14. An apparatus as recited in claim 5, wherein said packet decoder, said packet error detector, and said packet correction estimator comprise electronic hardware, or programming which executes on a computer processing element, or a combination of hardware and programming.

15. In a video streaming decoder configured for detecting erroneous packets, the improvement comprises:
estimating corrections for an erroneous packet in response to knowledge of field characteristics; and
applying correction to said erroneous packet to create a corrected packet.

16. The improvement as recited in claim 15, further comprising sending said corrected packet back into said decoder a sufficient number of times to provide a sufficient level of correction.

17. The improvement as recited in claim 15, further comprising limiting the time period or number of iterations over which estimation of corrections is performed on said erroneous packets.

18. The improvement as recited in claim 15, wherein said streaming packets comprise streaming media packets containing video, audio, or a combination of video and audio.

19. The improvement as recited in claim 15, wherein said knowledge of field characteristics is based on fields selected from the group of fields having fixed packet locations consisting essentially of: wireless header information, real-time transport protocol (RTP) header information, internet protocol (IP) header information, MPEG2 header information, duration field, sequence number field, payload type field, length field, time to live (TTL) field, protocol field, source IP address field and destination IP address field.

20. A method of decoding streaming data, comprising:
detecting at least one error in a packet being decoded;
estimating a packet correction for said erroneous packet in response to knowledge of field characteristics for the communication protocol of streaming data; and
applying correction to said packet; and
sending packet along to next driver level for further processing.

21. A method as recited in claim 20, wherein said estimating and applying of packet correction is performed during the decoding process.

22. A method as recited in claim 20, wherein said estimating and applying of correction to said packet is performed iteratively.

23. A method as recited in claim 20, wherein said knowledge of field characteristics comprises a knowledge of how the field changes with respect to time, packet sequence, or combination of time and packet sequence.

24. A method as recited in claim 20, wherein said knowledge of field characteristics comprises a knowledge of how the field changes in relation to other sequential packets in the packet stream.

25. A method as recited in claim 20, wherein said knowledge of field characteristics is based on fields selected from the group of fields having fixed packet locations consisting essentially of: wireless header information, real-time transport protocol (RTP) header information, internet protocol (IP) header information, MPEG2 header information, duration field, sequence number field, payload type field, length field, time to live (TTL) field, protocol field, source IP address field and destination IP address field.

26. A method as recited in claim 20, wherein said streaming packets comprise streaming media packets containing video, audio, or a combination of video and audio.

27. A method as recited in claim 26, wherein said streaming packets comprise MPEG-2 stream packets.

28. A method as recited in claim 25, wherein said method is executed in electronic hardware, programming which executes on a computer processing element, or a combination of hardware and programming.

29. A method as recited in claim 25, further comprising performing estimating of packet corrections in response to information received during decoding or from a subsequent processing stage to which correct packets, or corrected packets are directed.

30. A method of decoding streaming data, comprising:
decoding a packet;
detecting that said packet is erroneous, or sending a correct packet along to a next driver level for further processing;
estimating a packet correction for said erroneous packet in response to knowledge of field characteristics;
applying correction to said packet; and
sending corrected packet back to decoder for error checking.

31. A method as recited in claim 30, wherein said knowledge of field characteristics comprises a knowledge of how the field changes with respect to time, packet sequence, or in relation to other fields in the past, present or future.

32. A method as recited in claim 30, wherein said knowledge of field characteristics comprises a knowledge of how the field changes in relation to previous packets.

33. A method as recited in claim 30, wherein said streaming data comprises streaming data according to the MPEG-2 standard.

34. A method as recited in claim 30, further comprising finalizing correction in response to reaching a correction period threshold.

35. A method as recited in claim 34, wherein a corrected packet is sent to the next driver level.

36. A method as recited in claim 34, wherein said corrected packet comprises said erroneous packet which has been corrected to contain the least error in response to multiple correction estimation attempts.

37. A method as recited in claim 30, further comprising concealing errors received prior to or within said next driver level.
